(19) United States
(12) Patent Application Publication
(10) Pub. No.: US 2025/0157517 A1
(43) Pub. Date: May 15, 2025

(54) NON-VOLATILE STORAGE DEVICE

(71) Applicant: SONY SEMICONDUCTOR SOLUTIONS CORPORATION, KANAGAWA (JP)

(72) Inventor: YUSUKE SHUTO, KANAGAWA (JP)

(21) Appl. No.: 18/865,781

(22) PCT Filed: Mar. 28, 2023
(86) PCT No.: PCT/JP2023/012469

§ 371 Date: Nov. 14, 2024

(30) Foreign Application Priority Data
May 23, 2022 (JP) 2022-083643

(51) Int. Cl. G11C 11/16

(52) U.S. Cl. CPC G11C 11/1659; G11C 11/1655; G11C 11/1657; G11C 11/1673

(57) ABSTRACT

A standard potential used to detect data stored in a memory cell is optimized according to an arrangement position of the memory cell. A non-volatile storage device includes memory cells and reference memory cells. The memory cells are arranged in a matrix in a row direction and a column direction, and store data used to generate a data potential transmitted in the column direction. The reference memory cells are dispersedly arranged in the column direction, and store reference data used to generate a standard potential at the time of detection of the data stored in the memory cells. A selection control circuit that controls a selection position of the reference memory cells on the basis of a selection position of the memory cells from which the data is read may be further included.

### TECHNICAL FIELD

The present technology relates to a non-volatile storage device. Specifically, the present technology relates to a non-volatile storage device in which a reference potential is used to detect data stored in a memory cell.

### BACKGROUND ART

The reference potential may be used to detect whether data read from a memory cell is a logical value 0 or 1. For example, there is a storage device that generates a standard potential by selecting a predetermined number of reference potentials from a plurality of reference potentials stored in a reference memory cell group, and amplifies data read from a data memory cell group with respect to the standard potential (See, for example, Patent Document 1.).

### CITATION LIST

### Patent Document

Patent Document 1: Japanese Patent Application Laid-Open No. 2021-96887

### SUMMARY OF THE INVENTION

### Problems to be Solved by the Invention

However, in the above-described conventional technique, the selection position of the reference memory cell cannot be changed according to an arrangement position of the memory cell. For this reason, it is not possible to reflect the voltage deviation caused by the wiring resistance at the time of transmission of the data potential generated on the basis of the data read from the memory cell to the standard potential, and there is a possibility that the detection accuracy of the data stored in the memory cell is deteriorated.

The present technology has been made in view of such a situation, and an object thereof is to optimize a standard potential used for detecting data stored in a memory cell according to an arrangement position of the memory cell.

### Solutions to Problems

The present technology has been made to solve the above-described problems, and a first aspect thereof is a non-volatile storage device including: memory cells that are arranged in a matrix in a row direction and a column direction and store data used to generate a data potential transmitted in the column direction; and reference memory cells that are dispersedly arranged in the column direction and store reference data used to generate a standard potential at a time of detection of the data stored in the memory cells. This brings about an effect that the selection position in the column direction of the reference memory cells can follow the selection position in the column direction of the memory cells from which data is read.

Furthermore, in the first aspect, a plurality of the memory cells may be continuously arranged between the reference memory cells along the column direction. This brings about an effect that the number of reference memory cells is smaller than the number of memory cells in a memory cell array.

Furthermore, in the first aspect, a selection control circuit that controls a selection position of the reference memory cells on the basis of a selection position of the memory cells from which the data is read may be further included. This brings about an effect that the standard potential used to detect the data stored in the memory cells is optimized according to the arrangement position of the memory cells.

Furthermore, in the first aspect, a word line that selects the memory cells in the row direction; a reference word line that selects the reference memory cells in the row direction; a standard potential generation circuit that generates the standard potential on the basis of a reference potential transmitted in the column direction; a sense amplifier that detects the data read from the memory cells on the basis of the data potential and the standard potential; and a reference word line driver that drives the reference word line selected on the basis of a selection position of the word line connected to the memory cells from which the data is read may be further included. This brings about an effect that the data read from the memory cells is detected on the basis of the standard potential reflecting the voltage deviation caused by the wiring resistance at the time of transmission of the data potential generated on the basis of the data read from the memory cells.

Furthermore, in the first aspect, a bit line commonly used for transmission of the data potential in the column direction and transmission of the reference potential in the column direction may be further included, and the sense amplifier may include: a data terminal connected to the bit line used for transmission of the data potential; and a reference terminal connected to the bit line used for transmission of the reference potential. This brings about an effect that the data read from the memory cells is detected on the basis of the data potential transmitted via the bit line and the standard potential.

Furthermore, in the first aspect, the standard potential generation circuit generates the standard potential on the basis of averaging of a plurality of the reference potentials transmitted through bit lines different from each other. This brings about an effect that an intermediate potential between the reference potentials generated from binary data stored in the reference memory cells is generated as the standard potential.

Furthermore, in the first aspect, the reference word line driver may select only one reference word line connected to the reference memory cells from which the reference data is read when the standard potential is generated. This brings about an effect that the reference memory cells having the closest distance in the column direction can be selected with respect to the memory cells from which data is read.

Furthermore, in the first aspect, the reference word line driver may drive the reference word line closest to the word line connected to the memory cells from which the data is read with respect to a distance in the column direction to the sense amplifier. This brings about an effect that the voltage deviation caused by the wiring resistance at the time of transmission of the data potential generated on the basis of the data read from the memory cells is reflected on the standard potential.

Furthermore, in the first aspect, the reference word line driver may select the reference word line on the basis of high-order bits of an address for selecting the memory cells. This brings about an effect that the reference memory cells having a short distance in the column direction are selected with respect to the memory cells from which data is read.

Furthermore, in the first aspect, each of the memory cells and the reference memory cells may include magnetoresistive memories, and resistance values of the magnetoresistive memories may be combined and stored in a plurality of the reference memory cells connected to the reference word line. This brings about an effect that the standard potential generated on the basis of binary data stored in the reference memory cells is subdivided.

Furthermore, in the first aspect, the reference word line driver may select a plurality of the reference word lines connected to the reference memory cells from which the reference data is read when the standard potential is generated. This brings about an effect that the standard potential generated on the basis of binary data stored in the reference memory cells is subdivided.

Furthermore, in the first aspect, the reference word line driver may select the reference word lines on the basis of at least one of high-order bits of an address for selecting the memory cells or a combination signal for designating a combination of the plurality of reference word lines. This brings about an effect that the degree of freedom of adjustment of the standard potential generated on the basis of binary data stored in the reference memory cells is expanded.

Furthermore, in the first aspect, each of the memory cells and the reference memory cells include magnetoresistive memories, resistance values of the magnetoresistive memories are combined and stored in a plurality of the reference memory cells connected to the reference word lines, and patterns of combinations of the resistance values stored in the plurality of the reference memory cells connected to the reference word lines different from each other are different from each other. This brings about an effect that the degree of freedom of adjustment of the standard potential generated on the basis of binary data stored in the reference memory cells is expanded.

Furthermore, in the first aspect, a plurality of blocks in which the memory cells and the reference memory cells are blocked in an array may be further included, an enable signal for individually activating the blocks may be input to the blocks, and the high-order bits of the address and the combination signal may be shared between the blocks. This brings about an effect of increasing the memory capacity while suppressing an increase in an area of the wiring through which the combination signal is transmitted.

### BRIEF DESCRIPTION OF DRAWINGS

FIG. 1 is a block diagram illustrating a configuration example of a non-volatile storage device according to a first embodiment.

FIG. 2 is a diagram illustrating a configuration example of a memory cell array and a sense amplifier according to the first embodiment.

FIG. 3 is a diagram illustrating an arrangement example of memory cells and reference memory cells in the memory cell array according to the first embodiment.

FIG. 4 is a diagram illustrating an example of a relationship between a selection position of the memory cells and a selection position of the reference memory cells according to the first embodiment.

FIG. 5 is a diagram illustrating a configuration example of the memory cell array, the sense amplifier, and a reference word line driver according to the first embodiment.

FIG. 6 is a circuit diagram illustrating a configuration example of the reference word line driver according to the first embodiment.

FIG. 7 is a diagram illustrating a configuration example of a memory cell array and a sense amplifier according to a second embodiment.

FIG. 8 is a diagram illustrating a connection example of MTJ elements of reference memory cells according to the second embodiment.

FIG. 9 is a diagram illustrating a method of combining resistance values of reference memory cells according to a third embodiment.

FIG. 10 is a diagram illustrating an arrangement example of the reference memory cells and a configuration example of a reference word line driver according to the third embodiment.

FIG. 11 is a circuit diagram illustrating a configuration example of the reference word line driver according to the third embodiment.

FIG. 12 is a diagram illustrating a method of combining resistance values of reference memory cells according to a fourth embodiment.

FIG. 13 is a diagram illustrating an arrangement example of the reference memory cells and a configuration example of a reference word line driver according to the fourth embodiment.

FIG. 14 is a circuit diagram illustrating a configuration example of the reference word line driver according to the fourth embodiment.

FIG. 15 is a circuit diagram illustrating a configuration example of a system provided with a non-volatile storage device according to a fifth embodiment.

FIG. 16 is a circuit diagram illustrating a configuration example of a semiconductor device provided with a non-volatile storage device according to a sixth embodiment.

FIG. 17 is a block diagram illustrating an example of an electronic device in which the non-volatile storage device is used.

### MODE FOR CARRYING OUT THE INVENTION

Modes for carrying out the present technology (hereinafter, referred to as embodiments) will be described below. The description will be given in the following order.
1. First embodiment (Example of selecting any reference word line among reference word lines dispersedly arranged in column direction)
2. Second embodiment (Example of selecting a plurality of reference word lines among reference word lines dispersedly arranged in column direction)
3. Third embodiment (Example in which plurality of reference word lines having short distance to sense amplifier is selected as selected word line from among reference word lines dispersedly arranged in column direction, and standard voltage is generated on basis of combination of resistance values of reference memory cells)
4. Fourth embodiment (Example in which plurality of arbitrary reference word lines is selected from among reference word lines dispersedly arranged in column direction, and standard voltage is generated on basis of combination of resistance values of reference memory cells)
5. Fifth embodiment (Example in which plurality of non-volatile storage devices and controller that controls reading and writing of plurality of non-volatile storage devices are systematized)
6. Sixth embodiment (Example in which plurality of non-volatile storage devices and controller that controls reading and writing of plurality of non-volatile storage devices are provided in semiconductor device)
7. Application example (Example of applying non-volatile storage device to electronic device)

### 1. First Embodiment

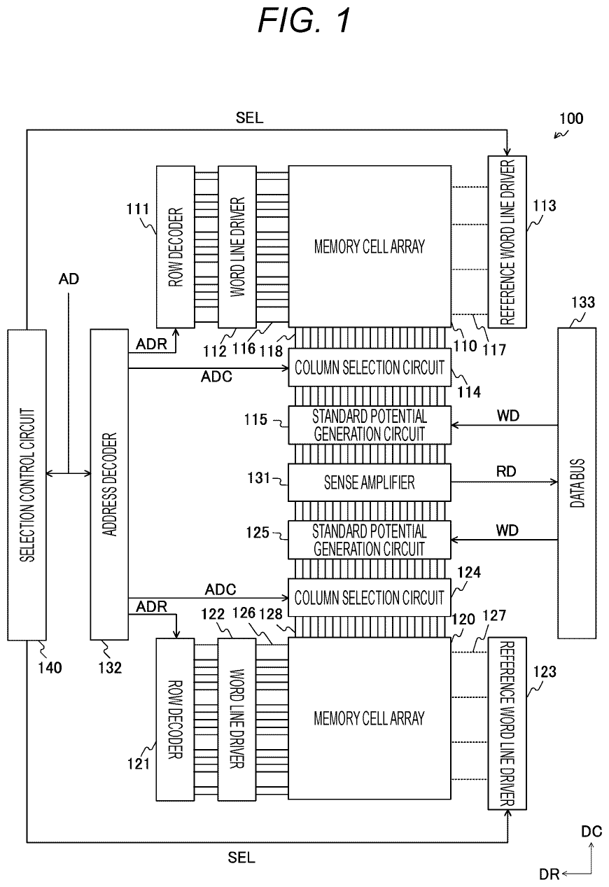

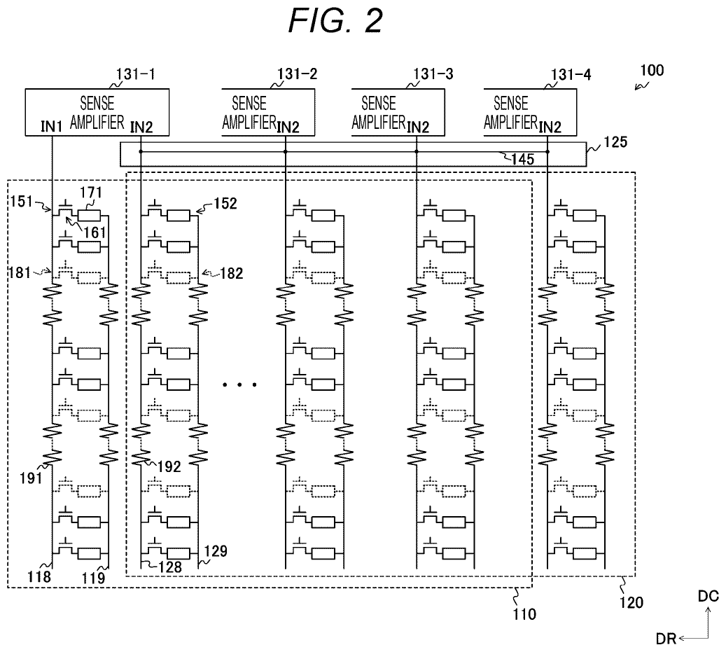

FIG. 1 is a block diagram illustrating a configuration example of a non-volatile storage device according to a first embodiment, and FIG. 2 is a diagram illustrating a configuration example of a memory cell array and a sense amplifier according to the first embodiment. Note that, in FIG. 2, memory cells 151 and 152 are indicated by solid lines, and reference memory cells 181 and 182 are indicated by dotted lines. In FIG. 2, in order to make it easy to understand a positional relationship between the reference memory cells 181 and 182 in the memory cell arrays 110 and 120, the memory cell array 110 is vertically inverted with respect to a position of a sense amplifier 131, and is illustrated to overlap the memory cell array 120. Furthermore, in FIG. 2, word lines 116 and 126 and reference word lines 117 and 127 in FIG. 1 are omitted. Furthermore, FIG. 2 illustrates an example in which the memory cell array 110 is used to read data from the memory cell 151 and the memory cell array 120 is used to read reference data from the reference memory cell 182.

In FIG. 1, a non-volatile storage device 100 includes memory cell arrays 110 and 120, row decoders 111 and 112, word line drivers 112 and 122, and reference word line drivers 113 and 123. Furthermore, the non-volatile storage device 100 includes column selection circuits 114 and 124, standard potential generation circuits 115 and 125, a sense amplifier 131, an address decoder 132, a data bus 133, and a selection control circuit 140. Note that the selection control circuit 140 may be provided in the non-volatile storage device 100 or may be provided outside the non-volatile storage device 100.

As illustrated in FIG. 2, in the memory cell array 110, memory cells 151 are arranged in a matrix in a row direction DR and a column direction DC. Furthermore, in the memory cell array 110, reference memory cells 181 are dispersedly arranged in the column direction DC. At this time, the reference memory cells 181 can be arranged in the memory cell array 110 to be isolated from each other in the column direction DC. One or more memory cells 151 can be arranged in the column direction DC between the reference memory cells 181 arranged to be isolated from each other in the column direction DC. At this time, a plurality of the memory cells 151 may be continuously arranged between the reference memory cells 181 along the column direction DC.

Furthermore, in the memory cell array 120, memory cells 152 are arranged in a matrix in the row direction DR and the column direction DC. Furthermore, in the memory cell array 120, reference memory cells 182 are dispersedly arranged in the column direction DC. At this time, the reference memory cells 182 can be arranged in the memory cell array 120 to be isolated from each other in the column direction DC. One or more memory cells 152 can be arranged in the column direction DC between the reference memory cells 182 arranged to be isolated from each other in the column direction DC. At this time, a plurality of the memory cells 152 may be continuously arranged between the reference memory cells 182 along the column direction DC.

Furthermore, in the memory cell arrays 110 and 120, the reference memory cells 181 and 182 can be arranged such that distances from the sense amplifier 131 in the column direction DC are equal to each other. At this time, the memory cell arrays 110 and 120 can be arranged vertically symmetrically with respect to the position of the sense amplifier 131.

Furthermore, the memory cell array 110 is provided with a word line 116 that selects the memory cells 151 in the row direction DR. The word line 116 is connected to the row decoder 111 via the word line driver 112. Moreover, the memory cell array 110 is provided with the reference word line 117 that selects the reference memory cells 181 in the row direction DR. The reference word line 117 is connected to the reference word line driver 113.

Furthermore, the memory cell array 120 is provided with the word line 126 that selects the memory cells 152 in the row direction DR. The word line 126 is connected to the row decoder 121 via the word line driver 122. Moreover, the memory cell array 120 is provided with the reference word line 127 that selects the reference memory cells 182 in the row direction DR. The reference word line 127 is connected to the reference word line driver 123.

Furthermore, a bit line 118 and a source line 119 are provided in the memory cell array 110. The bit line 118 and the source line 119 can be shared by the memory cells 151 and the reference memory cells 181. At this time, when data is read from the memory cells 151, the bit line 118 can transmit in the column direction DC a data potential generated on the basis of the data read from the memory cells 151. Here, when the data potential is transmitted in the column direction DC via the bit line 118, a voltage drop due to a parasitic resistance 191 of the bit line 118 occurs. This voltage drop varies depending on a distance in the column direction DC between each of the memory cells 151 and the sense amplifier 131.

Furthermore, when data is read from the reference memory cells 181, the bit line 118 can transmit in the column direction DC a reference potential generated on the basis of a reference data read from the reference memory cells 181. Here, when the reference potential is transmitted in the column direction DC via the bit line 118, a voltage drop due to the parasitic resistance 191 of the bit line 118 occurs. This voltage drop varies depending on a distance in the column direction DC between each of the reference memory cells 181 and the sense amplifier 131. The bit line 118 is connected to the sense amplifier 131 via the column selection circuit 114 and the standard potential generation circuit 115.

Furthermore, a bit line 128 and a source line 129 are provided in the memory cell array 120. The bit line 128 and the source line 129 can be shared by the memory cells 152 and the reference memory cells 182. At this time, when data is read from the memory cells 152, the bit line 128 can transmit in the column direction DC a data potential generated on the basis of the data read from the memory cells 152. Here, when the data potential is transmitted in the column direction DC via the bit line 128, a voltage drop due to a parasitic resistance 192 of the bit line 128 occurs. This voltage drop varies depending on a distance in the column direction DC between each of the memory cells 152 and the sense amplifier 131.

Furthermore, when data is read from the reference memory cells 182, the bit line 128 can transmit in the column direction DC a reference potential generated on the basis of a reference data read from the reference memory cells 182. Here, when the reference potential is transmitted in the column direction DC via the bit line 128, a voltage drop due to the parasitic resistance 192 of the bit line 128 occurs. This voltage drop varies depending on the distance in the column direction DC between each of the reference memory cells 182 and the sense amplifier 131. The bit line 128 is connected to the sense amplifier 131 via the column selection circuit 124 and the standard potential generation circuit 125.

The row decoder 111 selects the word line 116 on the basis of a row address ADR. The row decoder 121 selects the word line 126 on the basis of a row address ADR.

The word line driver 112 drives the word line 116 selected by the row decoder 111. The word line driver 122 drives the word line 126 selected by the row decoder 121.

The reference word line driver 113 drives the reference word line 117 selected on the basis of a reference word line designation signal SEL for designating a selection position of the reference word line 117. The reference word line driver 113 may drive only one reference word line 117 or may drive a plurality of the reference word lines connected to the reference memory cells 181 from which the reference data is read at the time of generating the standard potential. The reference word line driver 113 may drive the reference word line 117 closest to the word line 126 connected to the memory cells 152 from which data is read with respect to a distance in the column direction DC to the sense amplifier 131. The reference word line driver 113 may drive the reference word line 117 on the basis of high-order bits of an address AD for selecting the memory cells 152.

The reference word line driver 123 drives the reference word line 127 selected on the basis of the reference word line designation signal SEL for designating a selection position of the reference word line 127. The reference word line driver 123 may drive only one reference word line 127 or may drive a plurality of the reference word lines connected to the reference memory cells 182 from which the reference data is read at the time of generating the standard potential. The reference word line driver 123 may drive the reference word line 127 closest to the word line 116 connected to the memory cells 151 from which data is read with respect to a distance in the column direction DC to the sense amplifier 131. The reference word line driver 123 may drive the reference word line 127 on the basis of high-order bits of an address AD for selecting the memory cells 151.

The column selection circuit 114 selects the bit line 118 on the basis of a column address ADC. The column selection circuit 124 selects the bit line 128 on the basis of a column address ADC.

The standard potential generation circuit 115 generates a standard potential on the basis of the reference potential transmitted in the column direction DC via the bit line 118. For example, the standard potential generation circuit 115 can generate the standard potential on the basis of averaging of a plurality of reference potentials transmitted via different bit lines 118 of the memory cell array 110. The standard potential generation circuit 125 generates a standard potential on the basis of the reference potential transmitted in the column direction DC via the bit line 128. For example, the standard potential generation circuit 125 can generate the standard potential on the basis of averaging of a plurality of reference potentials transmitted via different bit lines 128 of the memory cell array 120. For example, as illustrated in FIG. 2, the standard potential generation circuit 125 may include a common connection 145 that short-circuits the different bit lines 128 of the memory cell array 120.

The sense amplifier 131 detects data read from the memory cells 151 on the basis of the data potential transmitted via the bit line 118 and the standard potential generated from the reference potential transmitted via the bit line 128. Furthermore, the sense amplifier 131 detects data read from the memory cells 152 on the basis of the standard potential generated from the reference potential transmitted via the bit line 118 and the data potential transmitted via the bit line 128.

As illustrated in FIG. 2, the sense amplifier 131 may include a plurality of sense amplifiers 131-1 to 131-4. The sense amplifiers 131-1 to 131-4 may be provided for each bit line 118 or for each of a plurality of the bit lines 118. Each of the sense amplifiers 131-1 to 131-4 includes two input terminals IN1 and IN2. When the bit line 118 is used for transmission of the data potential and the bit line 128 is used for transmission of the reference potential, the input terminal IN1 is used as a data terminal to which the data potential is input, and the input terminal IN2 is used as a reference terminal to which the reference potential is input. When the bit line 118 is used for transmission of the reference potential and the bit line 128 is used for transmission of the data potential, the input terminal IN1 is used as a reference terminal to which the reference potential is input, and the input terminal IN2 is used as a data terminal to which the data potential is input. FIG. 2 illustrates an example in which the input terminal IN1 is used as a data terminal and the input terminal IN2 is used as a reference terminal.

The address decoder 132 generates the row address ADR and the column address ADC on the basis of the address AD for selecting each of the memory cells 151 and 152. Then, the address decoder 132 inputs the row address ADR to each of the row decoders 111 and 121, and inputs the column address ADC to each of the column selection circuits 114 and 124.

The data bus 133 transmits write data WD input from the outside to each of the standard potential generation circuits 115 and 125, and transmits read data RD output from the sense amplifier 131 to the outside.

The selection control circuit 140 controls the selection position of each of the reference memory cells 181 and 182 in the column direction DC on the basis of the selection position of each of the memory cells 151 and 152 from which data is read. For example, the selection control circuit 140 may select the reference word line 127 closest to the word line 116 connected to the memory cells 151 from which data is read with respect to a distance in the column direction DC to the sense amplifier 131. Alternatively, the selection control circuit 140 may select the reference word line 117 closest to the word line 126 connected to the memory cells 152 from which data is read with respect to a distance in the column direction DC to the sense amplifier 131.

The selection control circuit 140 can output the reference word line designation signal SEL to the reference word line drivers 113 and 123 to control the selection position of each of the reference memory cells 181 and 182. The reference word line designation signal SEL may include high-order bits of the address AD that designates the memory cells 151 and 152 from which data is read.

Each of the memory cells 151 and 152 stores data. Each of the reference memory cells 181 and 182 stores reference data. The reference data is data used to generate a standard voltage for determining whether the data stored in each of the memory cells 151 and 152 is a logical value 0 or 1. Each of the memory cells 151 includes a transistor 161 and a magnetic tunnel junction (MTJ) element 171. The transistor 161 is, for example, a field effect transistor. The MTJ element 171 stores a resistance value. The MTJ element 171 includes a tunnel barrier layer sandwiched between magnetic layers. At this time, the MTJ element 171 can transition between two states, a low resistance state and a high resistance state. By associating these two states with the logical values 0 and 1, binary data can be stored in each of the memory cells 151 and 152. The memory cells 152 and the reference memory cells 181 and 182 can be configured similarly to the memory cells 151.

Note that each of the memory cells 151 and 152 and each of the reference memory cells 181 and 182 may be a magnetoresistive random access memory (MRAMV), a resistive random access memory (RRAM), or a phase-change memory (PCM). Alternatively, each of the memory cells 151 and 152 and each of the reference memory cells 181 and 182 may be a carbon nanotube memory (nanotube RAM (NRAM)) or a ferroelectric tunnel junction memory ((FTJ) memory). The MRAM may be a spin orbit torque (SOT)-MRAM, a spin transfer torque (STT)-MRAM, or a voltage controlled (VC)-MRAM.

Then, for example, it is assumed that data is read from the memory cell array 110. At this time, an address AD designating the memory cell 151 from which data is read is input to the address decoder 132 and the selection control circuit 140.

The address decoder 132 decodes the address AD and generates a row address ADR and a column address ADC. Then, the address decoder 132 inputs the row address ADR to the row decoder 111 and inputs the column address ADC to the column selection circuits 114 and 124.

The row decoder 111 selects the word line 116 connected to the memory cells 151 from which data is read on the basis of the row address ADR. At this time, the word line driver 112 drives the word line 116 selected by the row decoder 111 and activates the word line 116.

Furthermore, the column selection circuit 114 selects the bit line 118 connected to the memory cells 151 from which data is read on the basis of the column address ADC. Then, the bit line 118 selected by the column selection circuit 114 is connected to the sense amplifier 131 via the standard potential generation circuit 115, and the bit line 118 is activated. When the bit line 118 is activated, a data potential according to data read from the memory cells 151 is generated and transmitted to the sense amplifier 131 via the bit line 118.

On the other hand, the selection control circuit 140 generates the reference word line designation signal SEL on the basis of the address AD designating the memory cells 151 from which data is read, and inputs the reference word line designation signal to the reference word line driver 123. The reference word line designation signal SEL may be high-order bits of the address AD that designates the memory cells 151 from which data is read. The reference word line driver 123 selects the reference word line 127 on the basis of the reference word line designation signal SEL, and drives the selected reference word line 127 to activate the reference word line 127.

Furthermore, the column selection circuit 124 selects a plurality of the bit lines 128 connected to the reference memory cells 182 from which the reference data is read on the basis of the column address ADC. Then, the plurality of bit lines 128 selected by the column selection circuit 124 is connected to the sense amplifier 131 via the standard potential generation circuit 125, and the plurality of bit lines 128 is activated. When the plurality of bit lines 128 is activated, reference potentials according to the reference data read from the plurality of reference memory cells 182 is generated and transmitted to the sense amplifier 131 via the bit lines 128. At this time, the standard potential generation circuit 125 generates a standard potential on the basis of these reference potentials and inputs the reference potentials to the sense amplifier 131. For example, as illustrated in FIG. 2, the standard potential generation circuit 125 can generate a standard potential obtained by averaging a plurality of the reference potentials by short-circuiting the plurality of activated bit lines 128 by the common connection 145 and input the standard potential to the sense amplifier 131.

At this time, as illustrated in FIG. 2, for example, the data potential is input to the input terminal IN1 of the sense amplifier 131-1 via the bit line 118, and the standard potential generated by the standard potential generation circuit 125 is input to the input terminal IN2 of the sense amplifier 131-1 via the bit line 128. The sense amplifier 131-1 compares the standard potential generated by the standard potential generation circuit 125 with the data potential to determine whether the data read from the memory cells 151 is a logical value 0 or 1.

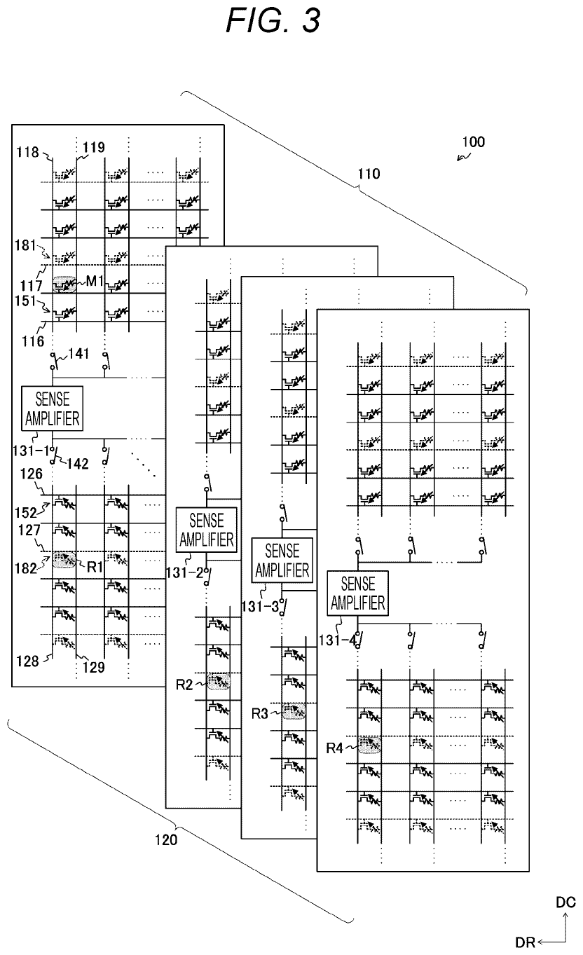

FIG. 3 is a diagram illustrating an arrangement example of the memory cells and reference memory cells in the memory cell array according to the first embodiment.

In the drawing, the memory cell arrays 110 and 120 are arranged vertically symmetrically with respect to the position of the sense amplifier 131. The column selection circuit 114 can include a switch 141 that connects each bit line 118 to the sense amplifier 131. The column selection circuit 124 can include a switch 142 that connects each bit line 128 to the sense amplifier 131.

Here, when the memory cells 151 from which data is read are selected from the memory cell array 110, the reference memory cells 182 from which reference data is read are selected from the memory cell array 120. When the memory cells 152 from which data is read are selected from the memory cell array 120, the reference memory cells 181 from which reference data is read are selected from the memory cell array 110.

For example, it is assumed that data is read from the memory cell 151 at a selection position M1 among the memory cells 151 of the memory cell array 110. At this time, the reference data can be read from the reference memory cells 182 at the selection positions R1 to R4 among the reference memory cells 182 of the memory cell array 120.

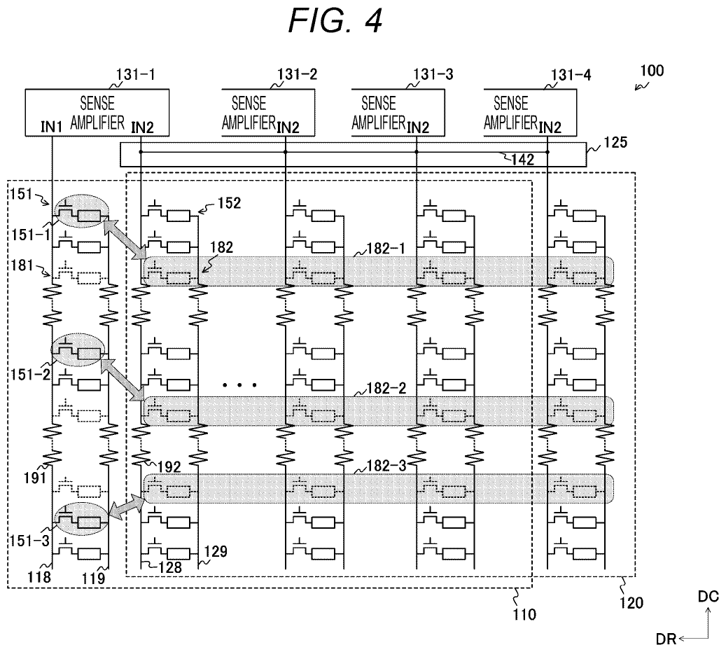

FIG. 4 is a diagram illustrating an example of a relationship between a selection position of the memory cells and a selection position of the reference memory cells according to the first embodiment. Note that, in FIG. 4, the memory cell arrays 110 and 120 are arranged in the same manner as in FIG. 2.

In the drawing, in the memory cell array 120, a plurality of the reference memory cells 182 is arranged at positions 182-1 to 182-3 where lengths of the bit lines 128 to the sense amplifiers 131 are different from each other. Then, it is assumed that data is read from the memory cell 151 at a selection position 151-1 among the memory cells 151 of the memory cell array 110. Here, it is assumed that the length of the bit line 128 from the reference memory cell 182 at the position 182-1 to the sense amplifier 131 is closest to the length of the bit line 118 from the memory cell 151 at the selection position 151-1 to the sense amplifier 131. At this time, the reference memory cell 182 at the position 182-1 is selected. The word line driver 112 drives the word line 116 connected to the memory cell 151 at the selection position 151-1, and the reference word line driver 123 drives the reference word line 127 connected to the reference memory cell 182 at the position 182-1.

Here, the data potential generated on the basis of the data read from the memory cell 151 at the selection position 151-1 is transmitted to the sense amplifier 131 via the bit line 118. The reference potential generated on the basis of the reference data read from the reference memory cell 182 at the position 182-1 is transmitted to the sense amplifier 131 via the bit line 128. At this time, a voltage drop caused by the parasitic resistance 191 of the bit line 118 occurs in the data potential input to the sense amplifier 131, and a voltage drop caused by the parasitic resistance 192 of the bit line 128 occurs in the reference potential input to the sense amplifier 131. Here, when data is read from the memory cell 151 at the selection position 151-1, the reference memory cell 182 at the position 182-1 is selected. Therefore, a difference between the length of the bit line 128 from the reference memory cell 182 at the position 182-1 to the sense amplifier 131 and the length of the bit line 118 from the memory cell 151 at the selection position 151-1 to the sense amplifier 131 can be reduced. As a result, it is possible to reduce a difference between the voltage drop caused by the parasitic resistance 192 from the reference memory cell 182 at the position 182-1 to the sense amplifier 131 and the voltage drop caused by the parasitic resistance 192 from the memory cell 151 at the selection position 151-1 to the sense amplifier 131.

It is assumed that data is read from the memory cell 151 at a selection position 151-2 among the memory cells 151 of the memory cell array 110. Here, it is assumed that the length of the bit line 128 from the reference memory cell 182 at the position 182-2 to the sense amplifier 131 is closest to the length of the bit line 118 from the memory cell 151 at the selection position 151-2 to the sense amplifier 131. At this time, the reference memory cell 182 at the position 182-2 is selected. Then, the word line driver 112 drives the word line 116 connected to the memory cell 151 at the selection position 151-2, and the reference word line driver 123 drives the reference word line 127 connected to the reference memory cell 182 at the position 182-2.

Here, when data is read from the memory cell 151 at the selection position 151-2, the reference memory cell 182 at the position 182-2 is selected. Therefore, a difference between the length of the bit line 128 from the reference memory cell 182 at the position 182-2 to the sense amplifier 131 and the length of the bit line 118 from the memory cell 151 at the selection position 152-1 to the sense amplifier 131 can be reduced. As a result, it is possible to reduce a difference between the voltage drop caused by the parasitic resistance 192 from the reference memory cell 182 at the position 182-2 to the sense amplifier 131 and the voltage drop caused by the parasitic resistance 192 from the memory cell 151 at the selection position 151-2 to the sense amplifier 131.

It is assumed that data is read from the memory cell 151 at a selection position 151-3 among the memory cells 151 of the memory cell array 110. Here, it is assumed that the length of the bit line 128 from the reference memory cell 182 at the position 182-3 to the sense amplifier 131 is closest to the length of the bit line 118 from the memory cell 151 at the selection position 151-3 to the sense amplifier 131. At this time, the reference memory cell 182 at the position 182-3 is selected. Then, the word line driver 112 drives the word line 116 connected to the memory cell 151 at the selection position 151-3, and the reference word line driver 123 drives the reference word line 127 connected to the reference memory cell 182 at the position 182-3.

Here, when data is read from the memory cell 151 at the selection position 151-3, the reference memory cell 182 at the position 182-3 is selected. Therefore, a difference between the length of the bit line 128 from the reference memory cell 182 at the position 182-3 to the sense amplifier 131 and the length of the bit line 118 from the memory cell 151 at the selection position 151-3 to the sense amplifier 131 can be reduced. As a result, it is possible to reduce a difference between the voltage drop caused by the parasitic resistance 192 from the reference memory cell 182 at the position 182-3 to the sense amplifier 131 and the voltage drop caused by the parasitic resistance 192 from the memory cell 151 at the selection position 151-3 to the sense amplifier 131.

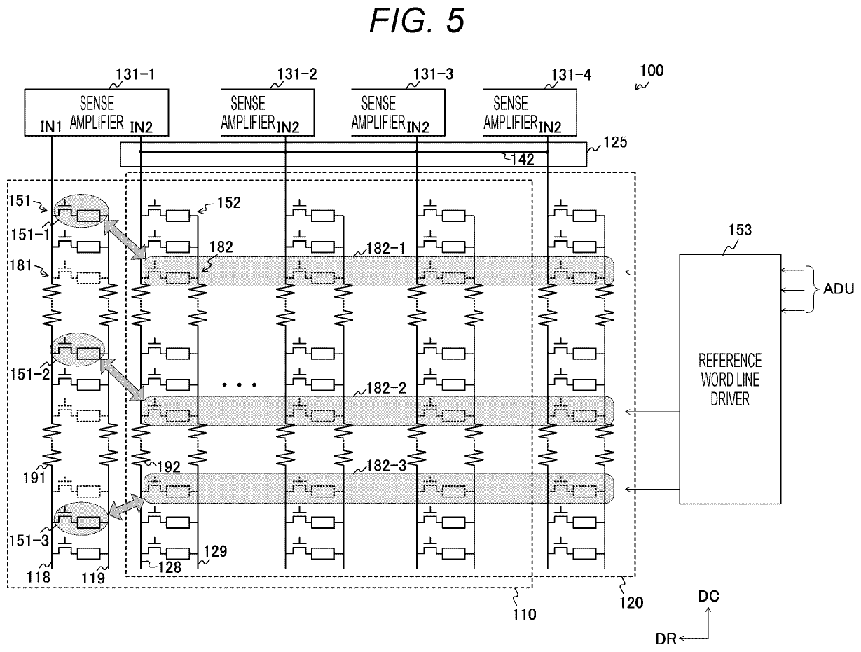

FIG. 5 is a diagram illustrating a configuration example of the memory cell array, the sense amplifier, and the reference word line driver according to the first embodiment. Note that, in FIG. 5, the memory cell arrays 110 and 120 are arranged similarly to FIG. 4.

In the drawing, for example, a reference word line driver 153 can be used as the reference word line driver 123 in FIG. 1. The reference word line driver 153 can select the reference word line 127 on the basis of the high-order bit ADU of the address AD, and drive the selected reference word line 127. The high-order bit ADU of the address AD can be given by <X:Y> in <X:0> of the address AD. Here, X and Y are positive integers and X>Y.

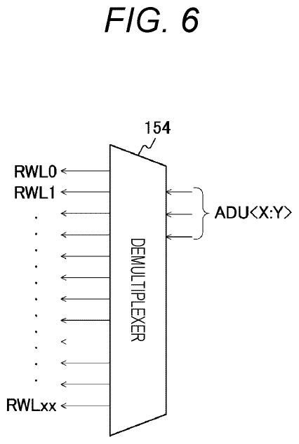

FIG. 6 is a circuit diagram illustrating a configuration example of the reference word line driver according to the first embodiment.

In the drawing, the reference word line driver 153 includes a demultiplexer 154. Furthermore, it is assumed that reference word lines RWL0 to RWLxx (xx is an integer of 1 or more) are provided as the reference word line 127. At this time, the demultiplexer 154 can select any one of the reference word lines RWL0 to RWLxx on the basis of the high-order bit ADU<X:Y> of the address AD, and drive the selected reference word line 127.

As described above, in the first embodiment described above, the reference word line driver 123 selects one of the reference word lines 127 dispersedly arranged in the column direction DC on the basis of the selection position of the memory cell 151 from which data is read. As a result, it is possible to reduce a difference between the voltage drop caused by the parasitic resistance 191 from the memory cell 151 from which data is read to the sense amplifier 131 and the voltage drop caused by the parasitic resistance 192 from the reference memory cell 182 used at that time to the sense amplifier 131. Therefore, even in a case where the memory cells 151 are arranged in a matrix in the row direction DR and the column direction DC, the read margin of the data stored in the memory cells 151 can be improved.

Furthermore, by increasing the number of reference word lines 117 and 127 dispersedly arranged in the column direction DC, it is possible to lengthen the bit lines 118 and 182 while suppressing a decrease in the read margin of the data stored in the memory cells 151 and 152. Therefore, it is possible to improve the number of integrated memory cells 151 while suppressing a decrease in the reading accuracy of the data stored in the memory cells 151, and it is possible to improve the memory capacity per chip.

Moreover, by selecting one of the reference word lines 127 on the basis of the selection position of the memory cell 151 from which data is read, it is possible to suppress concentration of access to a specific reference memory cell 182. For this reason, deterioration of the read characteristics of the reference memory cells 182 over time can be suppressed, and the life of the non-volatile storage device 100 can be extended.

### 2. Second Embodiment

In the first embodiment described above, one of the reference word lines 127 is selected on the basis of the selection position of the memory cells 151 from which data is read. In a second embodiment, a plurality of reference word lines 127 is selected on the basis of the selection position of the memory cells 151 from which data is read.

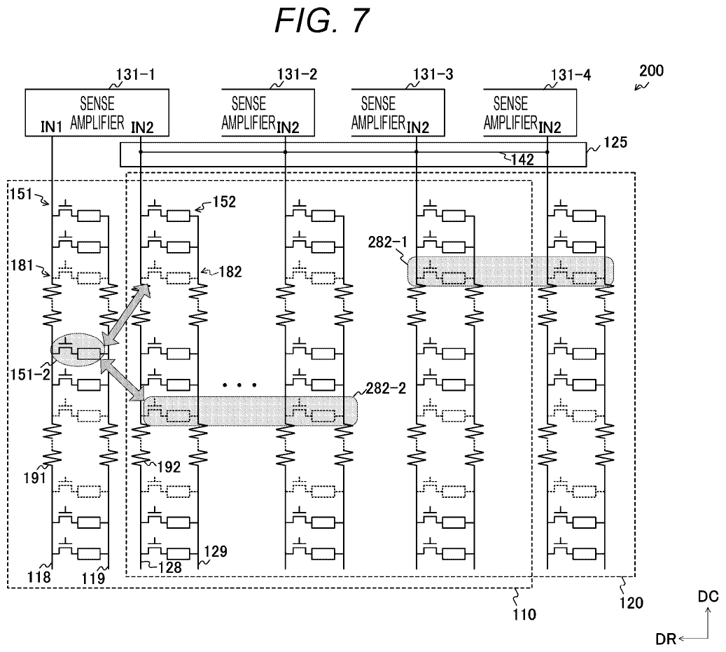

FIG. 7 is a diagram illustrating a configuration example of a memory cell array and a sense amplifier according to the second embodiment; Note that, in FIG. 7, memory cell arrays 110 and 120 are arranged similarly to FIG. 2.

In the drawing, a non-volatile storage device 200 has a configuration similar to that of the non-volatile storage device 100 of the first embodiment described above. However, the non-volatile storage device 100 of the above-described first embodiment selects one of the reference word lines 127 on the basis of the selection position of the memory cells 151 from which data is read. On the other hand, the non-volatile storage device 200 of the second embodiment selects a plurality of reference word lines 127 on the basis of the selection position of memory cells 151 from which data is read.

For example, it is assumed that data is read from the memory cell 151 at a selection position 151-2 among the memory cells 151 of the memory cell array 110. At this time, a reference memory cell 182 at a position 282-1 and a reference memory cell 182 at a position 282-2 connected to the reference word lines 127 different from each other are selected. Here, the length of the bit line 128 from the reference memory cell 182 at the position 282-1 to the sense amplifier 131 may be shorter than the length of the bit line 118 from the memory cell 151 at the selection position 151-2 to the sense amplifier 131. Furthermore, the length of the bit line 128 from the reference memory cell 182 at the position 282-2 to the sense amplifier 131 may be longer than the length of the bit line 118 from the memory cell 151 at the selection position 151-2 to the sense amplifier 131. The word line driver 112 drives the word line 116 connected to the memory cell 151 at the selection position 151-2. Furthermore, the reference word line driver 123 drives the reference word line 127 connected to the reference memory cell 182 at the position 282-1 and the reference word line 127 connected to the reference memory cell 182 at the position 282-2.

Here, a selection control circuit 140 selects the plurality of reference word lines 127 driven by a reference word line driver 113. At this time, when the plurality of reference word lines 127 is selected, parasitic resistances 192 of the bit lines 128 from the reference memory cells 182 to the sense amplifier 131 become a combined resistance of parasitic resistances 192 of the plurality of bit lines 128. In the example of FIG. 7, this combined resistance is a combined resistance of a parasitic resistance 192 of the bit line 128 from the reference memory cell 182 at the position 282-1 to the sense amplifier 131 and a parasitic resistance 192 of the bit line 128 from the reference memory cell 182 at the position 282-2 to the sense amplifier 131. At this time, the selection control circuit 140 may select the plurality of reference word lines 127 such that the combined resistance is equal to a parasitic resistance 191 of the bit line 118 from the memory cell 151 at the selection position 151-2 to the sense amplifier 131.

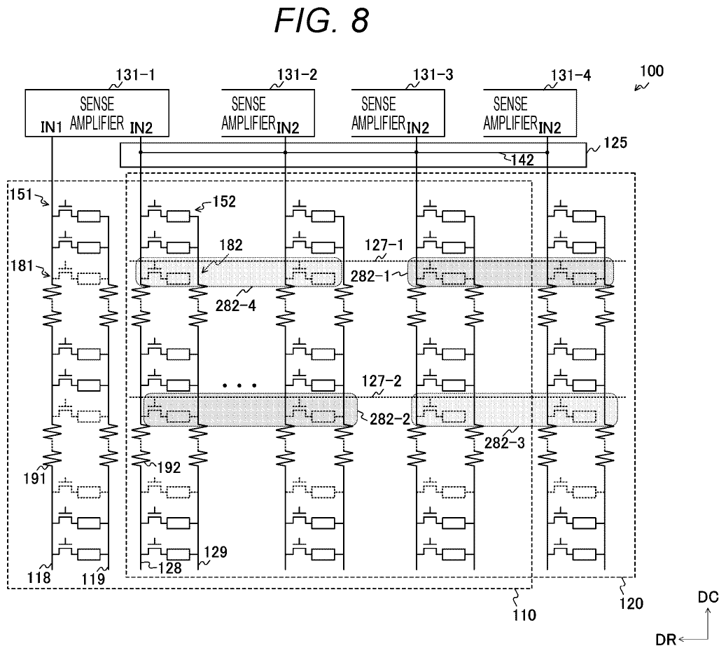

FIG. 8 is a diagram illustrating a connection example of an MTJ element of the reference memory cell according to the second embodiment. Note that, in FIG. 8, the memory cell arrays 110 and 120 are arranged similarly to FIG. 7.

In the drawing, in a case where the plurality of reference word lines 127 is selected, it is necessary to prevent reference data stored in the reference memory cells 182 connected to different reference word lines 127 from being read to the same bit line 128. At this time, the bit line 128 is shared with each other, and the connection of an MTJ element 171 is disconnected or the MTJ element 171 is removed except for any one of the reference memory cells 182 connected to the different reference word lines 127.

For example, the connection of the MTJ element 171 of the reference memory cell 182 at the position 282-3 and the reference memory cell 182 at the position 282-1 sharing the bit line 128 with each other may be disconnected. Furthermore, the connection of the MTJ element 171 of the reference memory cell 182 at the position 282-4 and the reference memory cell 182 at the position 282-2 sharing the bit line 128 with each other may be disconnected.

As described above, according to the second embodiment described above, by selecting the plurality of reference word lines 127 on the basis of the selection position of the memory cells 151 from which data is read, the standard potential that is the basis for determination of data read from the memory cells 151 can be finely adjusted. Therefore, it is possible to improve a read margin of data stored in the memory cells 151 while suppressing an increase in the number of reference word lines 127. As a result, it is possible to improve the reading accuracy of the data stored in the memory cells 151 while suppressing a decrease in the memory capacity per chip.

### 3. Third Embodiment

In the second embodiment described above, the plurality of reference word lines 127 is selected on the basis of the selection position of the memory cells 151 from which data is read. In a third embodiment, a plurality of reference word lines having a short distance to a sense amplifier 131 is selected as a selected word line from among reference word lines 127 dispersedly arranged in a column direction DC, and a standard voltage is generated on the basis of a combination of resistance values of reference memory cells 182.

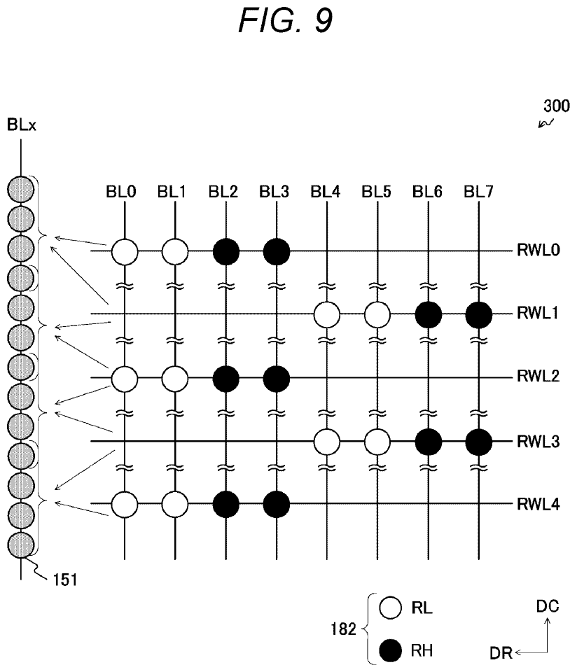

FIG. 9 is a diagram illustrating a method of combining resistance values of reference memory cells according to the third embodiment; Note that, in FIG. 9, memory cells 151 and the reference memory cells 182 are indicated by circles. A connection relationship of reference word lines RWL0 to RWL4 and bit lines BL0 to BL7 to the reference memory cells 182 is illustrated by arranging the reference memory cells 182 at intersection positions of the reference word lines RWL0 to RWL4 and the bit lines BL0 to BL7. Furthermore, the reference memory cell 182 storing a low resistance value RL is indicated by a white circle, and the reference memory cell 182 storing a high resistance value RH is indicated by a black circle. Furthermore, FIG. 9 illustrates an example in which the memory cells 151 are connected to the bit line BLx. BLx is one of the bit lines 118 of FIG. 1.

In the drawing, a non-volatile storage device 300 has a configuration similar to that of the non-volatile storage device 100 of the first embodiment described above. However, in the non-volatile storage device 300 of the third embodiment, a combination of the low resistance value RL and the high resistance value RH stored in the reference memory cells 182 can be arbitrarily set.

The non-volatile storage device 300 includes, for example, five reference word lines RWL0 to RWL4, and four reference memory cells 182 are connected to each of the reference word lines RWL0 to RWL4. In each of the reference memory cells 182, the low resistance value RL and the high resistance value RH are set in any combination. Then, when data is read from the memory cells 151, it is assumed that two of the five reference word lines RWL0 to RWL4 that are close in distance to the sense amplifier 130 from the word line 116 connected to the memory cell 151 are selected. Then, it is assumed that a standard potential is generated on the basis of each of reference potentials generated from reference data read from the eight reference memory cells 182. At this time, if only one of the five reference word lines RWL0 to RWL4 is selected, there are nine mixing ratios of the low resistance value RL and the high resistance value RH from 0:8 to 8:0. On the other hand, when two of the five reference word lines RWL0 to RWL4 are selected, the respective mixing ratios of the low resistance value RL and the high resistance value RH are 5 ratios of 0:4 to 4:0, and when these two ratios are combined, 5×5=25 ratios are obtained. The number of reference potentials that can be generated varies depending on the number of reference word lines 127 and the number of shared bit lines 128, but in any case, the number of standard potentials that can be generated can be increased as compared with a case where only one reference word line 127 is driven.

Note that the combination of the low resistance value RL and the high resistance value RH of the reference memory cells 182 can be determined such that the determination result of the data read from the memory cells 151 matches the data actually stored in the memory cells 151. Furthermore, the combination of the low resistance value RL and the high resistance value RH of the reference memory cells 182 may be changed according to the use environment or the change with time of the non-volatile storage device 300. For example, a temperature sensor that measures the temperature around the non-volatile storage device 300 may be mounted, and the combination of the low resistance value RL and the high resistance value RH of the reference memory cells 182 may be changed on the basis of a measurement result of the temperature by the temperature sensor.

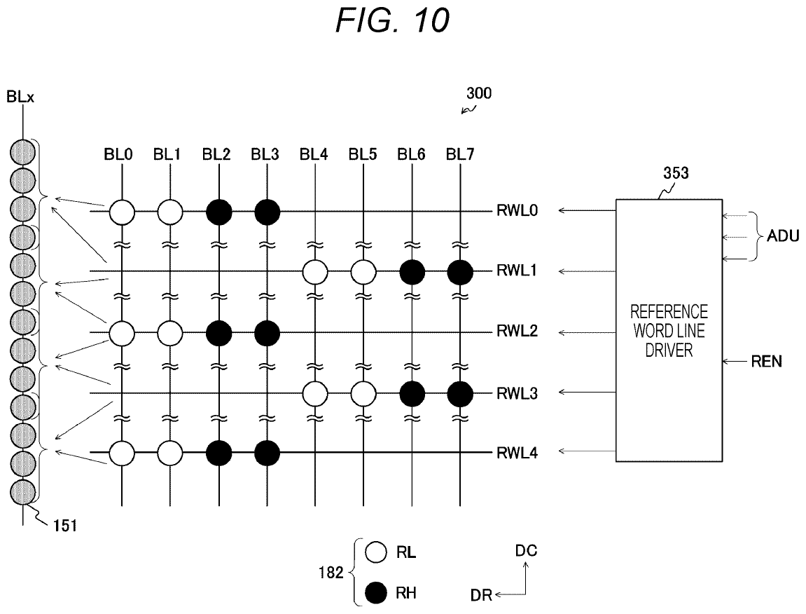

FIG. 10 is a diagram illustrating an arrangement example of reference memory cells and a configuration example of a reference word line driver according to the third embodiment. Note that, in FIG. 10, a connection relationship between the reference word lines RWL0 to RWL4 and the bit lines BL0 to BL7 with respect to the reference memory cells 182 is illustrated similarly to FIG. 9.

In the drawing, for example, a reference word line driver 353 can be used as the reference word line driver 123 in FIG. 1. The reference word line driver 353 can select the plurality of reference word lines RWL0 to RWL4 on the basis of the high-order bit ADU of the address AD and a reference word line enable signal REN, and drive the selected reference word lines. At this time, the reference word line driver 353 decodes the high-order bit ADU of the address AD. As a result, it is possible to select, from the five reference word lines RWL0 to RWL4, two lines having a short distance to the sense amplifier 131 from the word line 116 connected to the memory cell 151 from which data is read. Furthermore, the reference word line driver 353 can select whether to drive one or two of the five reference word lines RWL0 to RWL4 on the basis of the reference word line enable signal REN.

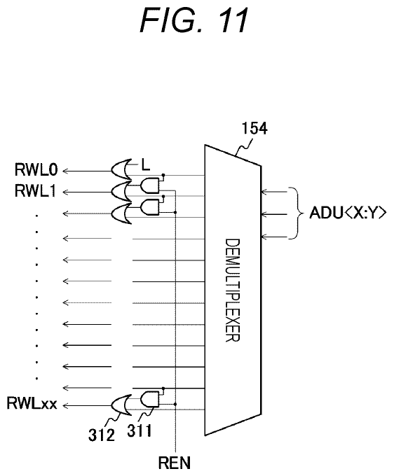

FIG. 11 is a circuit diagram illustrating a configuration example of the reference word line driver according to the third embodiment.

In the drawing, the reference word line driver 353 includes an AND circuit 311 and an OR circuit 312 in addition to the demultiplexer 154 of the first embodiment described above. The output of each OR circuit 312 is connected to the reference word lines RWL0 to RWLxx. Each AND circuit 311 performs an AND of the output of the demultiplexer 154 and the reference word line enable signal REN, and inputs the AND to the OR circuit 312. At this time, the output of the demultiplexer 154 is connected to the input of each AND circuit 311 such that the numbers of the reference word lines RWL0 to RWLxx connected to each OR circuit 312 are shifted by one. Each OR circuit 312 performs an OR of the output of the demultiplexer 154 and the output of each AND circuit 311, and inputs the OR to the reference word lines RWL0 to RWLxx. However, a low level L is input to the OR circuit 312 connected to the reference word line RWL0 instead of the output of the AND circuit 311.

Then, in a case where the reference word line enable signal REN is at the low level, the output of the demultiplexer 154 is directly input from the reference word line RWL0 to RWLxx. On the other hand, in a case where the reference word line enable signal REN is at a high level, two adjacent outputs of the demultiplexer 154 are input to the reference word lines RWL0 to RWLxx.

As described above, in the third embodiment described above, the number of selected reference word lines 127 driven at the time of generating the standard potential and the combination of the low resistance value RL and the high resistance value RH of the reference memory cells 182 can be changed. As a result, it is possible to finely set the standard potential used for determining the data read from the memory cells 151, and it is possible to improve the read margin of the data stored in the memory cells 151 while suppressing an increase in the number of reference word lines 127.

### 4. Fourth Embodiment

In the third embodiment described above, the plurality of reference word lines having a short distance to the sense amplifier 131 is selected as a selected word line from among the reference word lines 127, and the standard voltage is generated on the basis of a combination of the resistance values of the reference memory cells 182. In a fourth embodiment, a plurality of arbitrary reference word lines 127 is selected, and a standard voltage is generated on the basis of a combination of resistance values of reference memory cells 182.

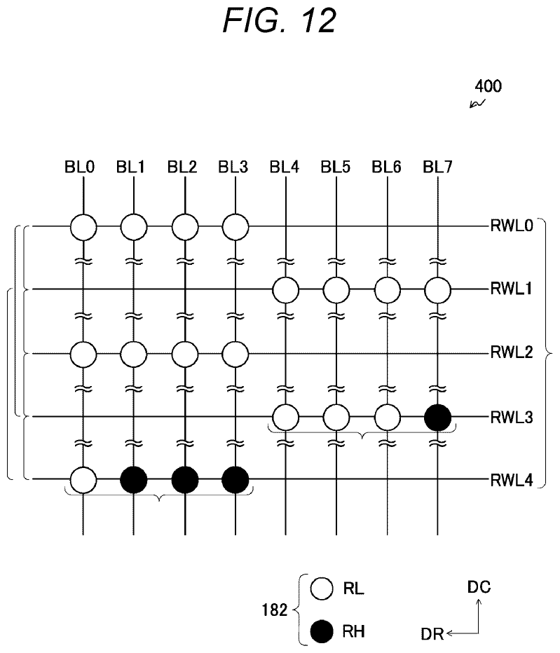

FIG. 12 is a diagram illustrating a method of combining resistance values of reference memory cells according to the fourth embodiment. Note that, in FIG. 12, a connection relationship between reference word lines RWL0 to RWL4 and bit lines BL0 to BL7 with respect to the reference memory cells 182 is illustrated similarly to FIG. 9.

In the drawing, a non-volatile storage device 400 has a configuration similar to that of the non-volatile storage device 100 of the first embodiment described above. However, the non-volatile storage device 400 of the fourth embodiment can select any plurality of reference word lines 127 and arbitrarily set a combination of a low resistance value RL and a high resistance value RH stored in the reference memory cells 182.

In the non-volatile storage device 400, any two of the five reference word lines RWL0 to RWL4 are selected when data is read from the memory cells 151. Then, it is assumed that a standard potential is generated on the basis of each of reference potentials generated from reference data read from the eight reference memory cells 182. At this time, if two of the five reference word lines RWL0 to RWL4 are selected, the respective mixing ratios of the low resistance value RL and the high resistance value RH are 5 ratios of 0:4 to 4:0, and when these two ratios are combined, 5×5=25 ratios are obtained. Moreover, assuming that any two of the five reference word lines RWL0 to RWL4 are selected, there are six combinations of the reference word lines RWL0 to RWL4: 0-1, 1-2, 2-3, 3-4, 0-3, and 1-4. As a result, the mixing ratio of the low resistance value RL and the high resistance value RH is 6×26=150, and 150 standard potentials can be generated.

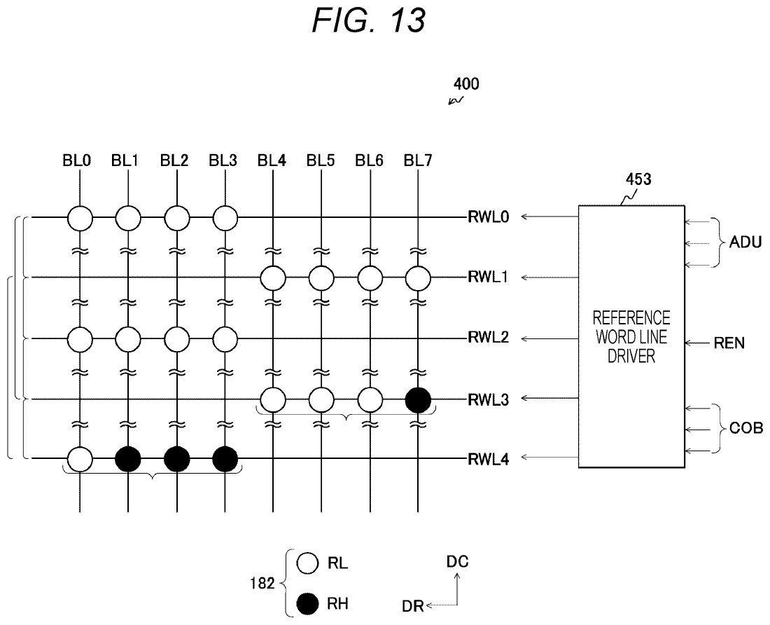

FIG. 13 is a diagram illustrating an arrangement example of the reference memory cells and a configuration example of the reference word line driver according to the fourth embodiment. Note that, in FIG. 13, a connection relationship between the reference word lines RWL0 to RWL4 and the bit lines BL0 to BL7 with respect to the reference memory cells 182 is illustrated similarly to FIG. 12.

In the drawing, for example, a reference word line driver 453 can be used as the reference word line driver 123 in FIG. 1. In addition to the high-order bit ADU of the address AD and the reference word line enable signal REN of the above-described third embodiment, a combination signal COB is input to the reference word line driver 453. The combination signal COB can designate any plurality of the reference word lines RWL0 to RWL4. At this time, the reference word line driver 453 can arbitrarily select the plurality of reference word lines RWL0 to RWL4 on the basis of the combination signal COB, and drive the selected reference word lines.

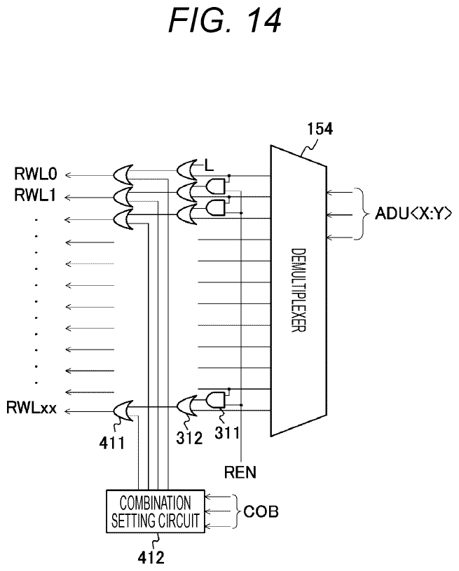

FIG. 14 is a circuit diagram illustrating a configuration example of the reference word line driver according to the fourth embodiment.

In the drawing, the reference word line driver 453 includes an OR circuit 411 and a combination setting circuit 412 in addition to the demultiplexer 154, the AND circuit 311, and the OR circuit 312 of the third embodiment described above. Each OR circuit 312 takes an OR of the output of the demultiplexer 154 and the output of each AND circuit 311, and inputs the OR to the OR circuit 411. Each OR circuit 411 performs an OR of the output of each AND circuit 311 and the output of the combination setting circuit 412, and inputs the OR to the reference word lines RWL0 to RWLxx. The combination setting circuit 412 generates a drive signal of an arbitrary combination of the reference word lines RWL0 to RWLxx on the basis of the combination signal COB, and inputs the drive signal to the OR circuit 411.

As described above, in the above-described fourth embodiment, the plurality of reference word lines 127 to be driven at the time of generating the standard potential is arbitrarily selected, and the combination of the low resistance value RL and the high resistance value RH of the reference memory cells 182 can be changed. As a result, it is possible to subdivide the standard potential used for determining the data read from the memory cells 151, and it is possible to improve the read margin of the data stored in the memory cells 151 while suppressing an increase in the number of reference word lines 127.

Note that one or more of the non-volatile storage devices 100 to 400 described above may be incorporated into a semiconductor device in which a controller that controls each of the non-volatile storage devices 100 to 400 is formed. Alternatively, one or more of the non-volatile storage devices 100 to 400 may be provided separately from the semiconductor device in which the controller controlling each of the non-volatile storage devices 100 to 400 is formed.

### 5. Fifth Embodiment

In the first embodiment described above, an operation example of one non-volatile storage device 100 has been described, but in a fifth embodiment, a reference word line designation signal SEL used to select a reference word line 127 is shared by a plurality of non-volatile storage devices.

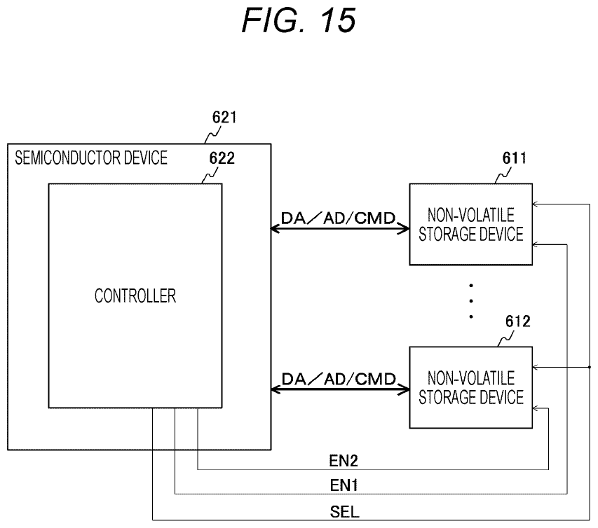

FIG. 15 is a circuit diagram illustrating a configuration example of a system in which non-volatile storage devices according to the fifth embodiment is provided.

In the drawing, each of non-volatile storage devices 611 and 612 is connected to a semiconductor device 621. Each of the non-volatile storage devices 611 and 612 may be any of the non-volatile storage devices 100 to 400 described above. Note that memory cell arrays 110 and 120 provided in the non-volatile storage devices 611 and 612 are examples of blocks recited in the claims. The semiconductor device 621 includes a controller 622. The controller 622 controls reading and writing of data DA with respect to each of the non-volatile storage devices 611 and 612. At this time, the controller 622 can exchange the data DA, an address AD, and a command CMD with the non-volatile storage devices 611 and 612. Furthermore, the controller 622 outputs an enable signal EN1 for activating the non-volatile storage device 611 to the non-volatile storage device 611, and outputs an enable signal EN2 for activating the non-volatile storage device 612 to the non-volatile storage device 612. Moreover, the controller 622 outputs the reference word line designation signal SEL to each of the non-volatile storage devices 611 and 612. Here, the reference word line designation signal SEL can be shared by the non-volatile storage devices 611 and 612. At this time, when causing the non-volatile storage device 611 to receive the reference word line designation signal SEL, the controller 622 can activate the non-volatile storage device 611 on the basis of the enable signal EN1. Furthermore, the controller 622 can activate the non-volatile storage device 612 on the basis of the enable signal EN2 when causing the non-volatile storage device 612 to receive the reference word line designation signal SEL. The reference word line designation signal SEL may include the high-order bit ADU of the address AD of the above-described first embodiment, or may include the high-order bit ADU of the address AD and the reference word line enable signal REN of the above-described third embodiment. The reference word line designation signal SEL may include the high-order bit ADU of the address AD, the reference word line enable signal REN, and the combination signal COB of the above-described fourth embodiment.

As described above, according to the above-described fifth embodiment, by sharing the reference word line designation signal SEL among a plurality of the non-volatile storage devices 611 and 612, it is possible to reduce an area of the wiring through which the reference word line designation signal SEL is transmitted.

### 6. Sixth Embodiment

In the above-described fifth embodiment, the plurality of non-volatile storage devices 611 and 612 in which the reference word line designation signal SEL used for selecting the reference word line 127 is shared is provided outside the semiconductor device 621. In a sixth embodiment, a plurality of non-volatile storage devices in which a reference word line designation signal SEL used to select a reference word line 127 is shared is provided in a semiconductor device.

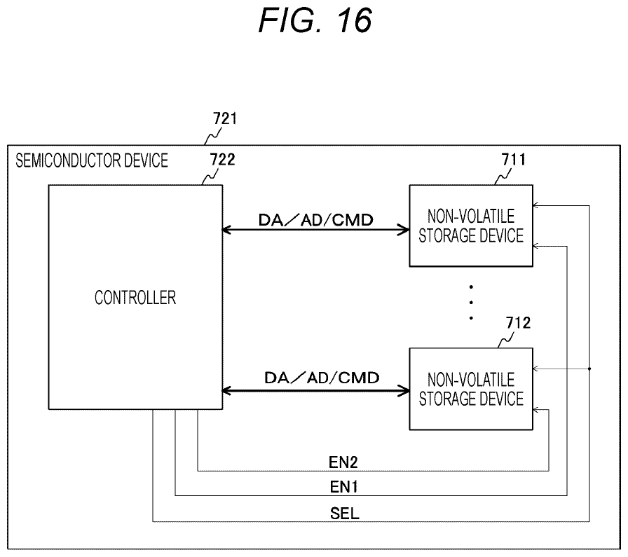

FIG. 16 is a circuit diagram illustrating a configuration example of a system in which non-volatile storage devices according to the sixth embodiment is provided.

In the drawing, a semiconductor device 721 is provided with non-volatile storage devices 711 and 712 and a controller 722. At this time, the non-volatile storage devices 711 and 712 and the controller 722 can be formed on one semiconductor chip. Each of the non-volatile storage devices 711 and 712 may be any of the non-volatile storage devices 100 to 400 described above. Note that memory cell arrays 110 and 120 provided in the non-volatile storage devices 711 and 712 are examples of blocks recited in the claims. The controller 722 controls reading and writing of data DA with respect to each of the non-volatile storage devices 711 and 712. At this time, the controller 722 can exchange the data DA, an address AD, and a command CMD with the non-volatile storage devices 711 and 712. Furthermore, the controller 722 outputs an enable signal EN1 for activating the non-volatile storage device 711 to the non-volatile storage device 711, and outputs an enable signal EN2 for activating the non-volatile storage device 712 to the non-volatile storage device 712. Moreover, the controller 722 outputs the reference word line designation signal SEL to each of the non-volatile storage devices 711 and 712. Here, the reference word line designation signal SEL can be shared by the non-volatile storage devices 711 and 712.

As described above, in the above-described sixth embodiment, by providing a plurality of the non-volatile storage devices 711 and 712 and the controller 722 in the semiconductor device 721, it is possible to increase the memory capacity mounted on the semiconductor device 721 while suppressing an increase in the mounting area.

### 7. Application Example

The technology according to the present disclosure (the present technology) can be applied to various products. For example, the technology according to the present disclosure may be achieved in the form of a device to be mounted on a mobile body of any kind, such as an automobile, an electric vehicle, a hybrid electric vehicle, a motorcycle, a bicycle, a personal mobility, an airplane, a drone, a vessel, or a robot. Furthermore, the technology according to the present disclosure may be realized as a device mounted on an entertainment main device, a communication device, an in-vehicle electronic device, an industrial machine, a home electronic device, an artificial satellite, and a computer.

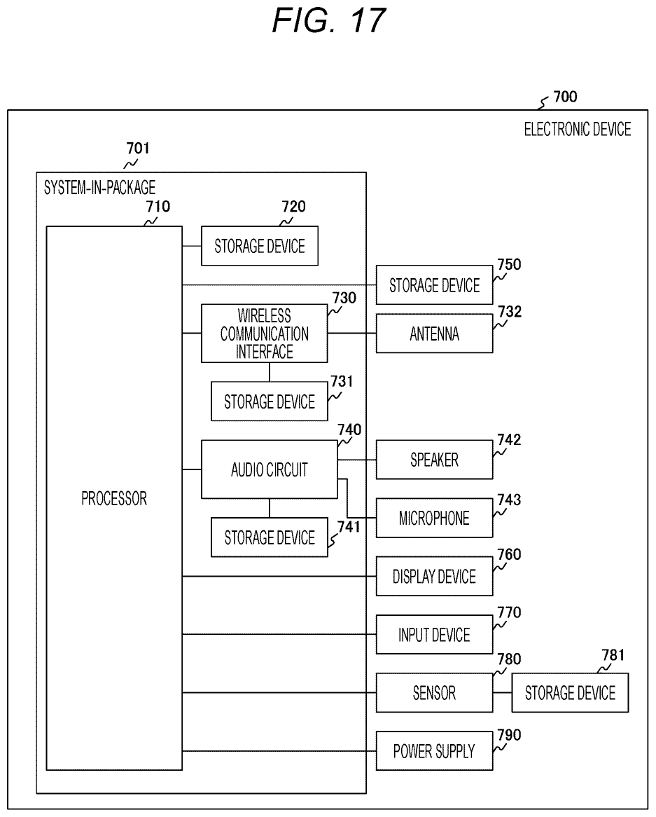

FIG. 17 is a block diagram illustrating an example of an electronic device in which a non-volatile storage device is used.

In the drawing, an electronic device 700 includes a system-in-package 701, storage devices 750 and 781, an antenna 732, a speaker 742, a microphone 743, a display device 760, an input device 770, a sensor 780, and a power supply 790. The system-in-package 701 includes a processor 710, storage devices 720, 731, and 741, a wireless communication interface 730, and an audio circuit 740.

The electronic device 700 is a smartphone, a digital camera, a digital video camera, a music player, a set-top box, a computer, a television, a clock, an active speaker, a headset, a game console, a radio, a measuring instrument, an electronic tag, a beacon, or the like.

The processor 710 is connected to the storage devices 720 and 750, the wireless communication interface 730, the audio circuit 740, the display device 760, the input device 770, the sensor 780, and the power supply 790. The antenna 732 is connected to the wireless communication interface 730. The storage device 741, the speaker 742, and the microphone 743 are connected to the audio circuit 740. The storage device 781 is connected to the sensor 780.

Note that each of the storage devices 720, 731, 741, 750, and 781 may be any of the non-volatile storage devices 100 to 400 described above. Each of the storage devices 720, 731, 741, 750, and 781 may be a combination of any of the non-volatile storage devices 100 to 400 described above and a volatile semiconductor storage device such as a dynamic random access memory (DRAM) or a static random access memory (SRAM).

The processor 710 is hardware that controls the operation of the entire electronic device 700. The processor 710 may be a central processing unit (CPU) or a graphics processing unit (GPU). The processor 710 may include a hardware circuit (for example, a field-programmable gate array (FPGA) or an application specific integrated circuit (ASIC)) such as an accelerator that performs a part of the processing.

The wireless communication interface 730 has a function of mobile communication, Wi-Fi (registered trademark), or near field communication.

The audio circuit 740 controls the speaker 742 and the microphone 743 to control input and output of sound such as voice and music.

The input device 770 is, for example, a keyboard, a mouse, a touch panel, a card reader, a barcode reader, a push button, or a voice input device.

The sensor 780 is, for example, an image sensor, an optical sensor, a position sensor, an acceleration sensor, a biological sensor, a magnetic sensor, a mechanical quantity sensor, a thermal sensor, an electric sensor, or a chemical sensor.

The power supply 790 may include a DC power supply such as a battery, or may include an AC/DC converter.

As described above, in the above-described application example, any one of the above-described non-volatile storage devices 100 to 400 is used as each of the storage devices 720, 731, 741, 750, and 781. As a result, the accuracy of reading data stored in each of the storage devices 720, 731, 741, 750, and 781 can be improved, and malfunction of the electronic device 700 can be prevented.

Note that the embodiments described above illustrate an example for embodying the present technology, and the matters in the embodiments and the matters specifying the invention in the claims have a correspondence relationship. Similarly, the matters specifying the invention in the claims and the matters with the same names in the embodiments of the present technology have correspondence relationships each. However, the present technology is not limited to the embodiments, and can be embodied by applying various modifications to the embodiments without departing from the scope of the present technology. Furthermore, effects described in the present specification are merely examples and are not limited, and other effects may be provided.

Note that the present technology may also have the following configuration.

(1) A non-volatile storage device including:
memory cells that are arranged in a matrix in a row direction and a column direction and store data used to generate a data potential transmitted in the column direction; and
reference memory cells that are dispersedly arranged in the column direction and store reference data used to generate a standard potential at a time of detection of the data stored in the memory cells.

(2) The non-volatile storage device according to (1), in which
a plurality of the memory cells is continuously arranged between the reference memory cells along the column direction.

(3) The non-volatile storage device according to (1) or (2), further including a selection control circuit that controls a selection position of the reference memory cells on the basis of a selection position of the memory cells from which the data is read.

(4) The non-volatile storage device according to any one of (1) to (3), further including:
a word line that selects the memory cells in the row direction;
a bit line that transmits in the column direction the data potential generated on the basis of the data read from the memory cells;
a reference word line that selects the reference memory cells in the row direction;
a bit line that transmits in the column direction a reference potential generated on the basis of the reference data read from the reference memory cells;
a standard potential generation circuit that generates the standard potential on the basis of the reference potential;
a sense amplifier that detects the data read from the memory cells on the basis of the data potential transmitted through the bit line and the standard potential transmitted through the bit line; and
a reference word line driver that drives the reference word line selected on the basis of a selection position of the word line connected to the memory cells from which the data is read.

(5) The non-volatile storage device according to (4), further including a bit line commonly used for transmission of the data potential in the column direction and transmission of the reference potential in the column direction,
in which the sense amplifier includes:
a data terminal connected to a bit line used for transmission of the data potential; and
a reference terminal connected to a bit line used for transmission of the reference potential.

(6) The non-volatile storage device according to (4) or (5), in which
the standard potential generation circuit generates the standard potential on the basis of averaging of a plurality of the reference potentials transmitted through bit lines different from each other.

(7) The non-volatile storage device according to any one of (4) to (6), in which
the reference word line driver selects only one reference word line connected to the reference memory cells from which the reference data is read when the standard potential is generated.

(8) The non-volatile storage device according to (7), in which
the reference word line driver drives the reference word line closest to the word line connected to the memory cells from which the data is read with respect to a distance in the column direction to the sense amplifier.

(9) The non-volatile storage device according to any one of (4) to (8), in which
the reference word line driver selects the reference word line on the basis of high-order bits of an address for selecting the memory cells.

(10) The non-volatile storage device according to any one of (4) to (9), in which
each of the memory cells and the reference memory cells include magnetoresistive memories, and
resistance values of the magnetoresistive memories are combined and stored in a plurality of the reference memory cells connected to the reference word line.

(11) The non-volatile storage device according to any one of (4) to (7), in which
the reference word line driver selects a plurality of the reference word lines connected to the reference memory cells from which the reference data is read when the standard potential is generated.

(12) The non-volatile storage device according to (11), in which
the reference word line driver selects the reference word lines on the basis of at least one of high-order bits of an address for selecting the memory cells or a combination signal for designating a combination of the plurality of reference word lines.

(13) The non-volatile storage device according to (11) or (12), in which
each of the memory cells and the reference memory cells include magnetoresistive memories,
resistance values of the magnetoresistive memories are combined and stored in a plurality of the reference memory cells connected to the reference word lines, and
patterns of combinations of the resistance values stored in the plurality of the respective reference memory cells connected to the reference word lines different from each other are different from each other.

(14) The non-volatile storage device according to any one of (1) to (13), further including
a plurality of blocks in which the memory cells and the reference memory cells are blocked in an array, in which an enable signal for individually activating the blocks is input to the blocks, and
the high-order bits of the address and the combination signal are shared between the blocks.

### REFERENCE SIGNS LIST

100 NON-VOLATILE STORAGE DEVICE
110, 120 Memory cell array
111, 121 Row decoder
112, 122 Word line driver
113, 123 Reference word line driver
114, 124 Column selection circuit
115, 125 Standard potential generation circuit
116, 126 Word line
117, 127 Reference word line
118, 128 Bit line
119, 129 Source line
131 Sense amplifier
132 Address decoder
133 Data bus
140 Selection control circuit
151, 152 Memory cell
161 Transistor
171 MTJ element
181, 182 Reference memory cell

1. A non-volatile storage device comprising:
memory cells that are arranged in a matrix in a row direction and a column direction and store data used to generate a data potential transmitted in the column direction; and
reference memory cells that are dispersedly arranged in the column direction and store reference data used to generate a standard potential at a time of detection of the data stored in the memory cells.

2. The non-volatile storage device according to claim 1, wherein
a plurality of the memory cells is continuously arranged between the reference memory cells along the column direction.

3. The non-volatile storage device according to claim 1, further comprising a selection control circuit that controls a selection position of the reference memory cells on a basis of a selection position of the memory cells from which the data is read.

4. The non-volatile storage device according to claim 1, further comprising:
a word line that selects the memory cells in the row direction;
a reference word line that selects the reference memory cells in the row direction;
a standard potential generation circuit that generates the standard potential on a basis of a reference potential transmitted in the column direction;
a sense amplifier that detects the data read from the memory cells on a basis of the data potential and the standard potential; and
a reference word line driver that drives the reference word line selected on a basis of a selection position of the word line connected to the memory cells from which the data is read.

5. The non-volatile storage device according to claim 4, further comprising a bit line commonly used for transmission of the data potential in the column direction and transmission of the reference potential in the column direction,
wherein the sense amplifier includes
a data terminal connected to a bit line used for transmission of the data potential, and
a reference terminal connected to a bit line used for transmission of the reference potential.

6. The non-volatile storage device according to claim 4, wherein
the standard potential generation circuit generates the standard potential on a basis of averaging of a plurality of the reference potentials transmitted through bit lines different from each other.

7. The non-volatile storage device according to claim 4, wherein
the reference word line driver drives only one reference word line connected to the reference memory cells from which the reference data is read when the standard potential is generated.

8. The non-volatile storage device according to claim 7, wherein
the reference word line driver drives the reference word line closest to the word line connected to the memory cells from which the data is read with respect to a distance in the column direction to the sense amplifier.

9. The non-volatile storage device according to claim 4, wherein
the reference word line driver drives the reference word line on a basis of high-order bits of an address for selecting the memory cells.

10. The non-volatile storage device according to claim 4, wherein
each of the memory cells and the reference memory cells include magnetoresistive memories, and
resistance values of the magnetoresistive memories are combined and stored in a plurality of the reference memory cells connected to the reference word line.

11. The non-volatile storage device according to claim 4, wherein
the reference word line driver drives a plurality of the reference word lines connected to the reference memory cells from which the reference data is read when the standard potential is generated.

12. The non-volatile storage device according to claim 11, wherein
the reference word line driver drives the reference word lines on a basis of at least one of high-order bits of an address for selecting the memory cells or a combination signal for designating a combination of the plurality of reference word lines.

13. The non-volatile storage device according to claim 12, wherein
each of the memory cells and the reference memory cells include magnetoresistive memories,
resistance values of the magnetoresistive memories are combined and stored in a plurality of the reference memory cells connected to the reference word lines, and
patterns of combinations of the resistance values stored in the plurality of the respective reference memory cells connected to the reference word lines different from each other are different from each other.

14. The non-volatile storage device according to claim 12, further comprising
a plurality of blocks in which the memory cells and the reference memory cells are blocked in an array,
wherein an enable signal for individually activating the blocks is input to the blocks, and
the high-order bits of the address and the combination signal are shared between the blocks.
